(19) United States
(12) Patent Application Publication
(10) Pub. No.: US 2009/0026614 A1
(43) Pub. Date: Jan. 29, 2009

(54) SYSTEM IN PACKAGE AND METHOD FOR FABRICATING THE SAME

(76) Inventor: Oh-Jin Jung, Bucheon-si (KR)

Correspondence Address: SHERR & VAUGHN, PLLC, 620 HERNDON PARKWAY, SUITE 200, HERNDON, VA, 20170, US

(21) Appl. No.: 12/168,969

(22) Filed: Jul. 8, 2008

(30) Foreign Application Priority Data
Jul. 23, 2007 (KR) 10-2007-0073544

(51) Int. Cl. H01L 23/488; H01L 21/44

(52) U.S. Cl. 257/738; 438/614; 257/E23.023; 257/E21.476

(57) ABSTRACT

A system device package that includes a semiconductor substrate, a metal line formed on the semiconductor substrate, a passivation film formed over the semiconductor substrate including the metal line, wherein the passivation film includes first and second openings, a pad formed over the passivation film and covering the first and second openings for connection to the metal line through the first opening, a via conductor extending through the pad, the passivation film and the semiconductor substrate such that the via conductor is in direct contact with the pad. The via conductor includes a first exposed end protruding from the pad and which serves as a first bump and a second exposed end protruding from the substrate that serves as a second bump. As a result, it is possible to reduce the total number of processes and fabrication costs and thus to improve fabrication efficiency.

The present application claims priority under 35 U.S.C. §119 to Korean Patent Application No. 10-2007-0073544 (filed on Jul. 23, 2007), which is hereby incorporated by reference in its entirety.

### BACKGROUND

With the trend towards mobile, miniaturized and multi-functional electronic devices, three-dimensional (3D) systems-in-packages (SIPs) having various chips realized in a single package have drawn a great deal of attention and interest. Portable equipment may have a structure in which semiconductor devices such as memory are separately embedded in the form of packages and are connected to each other. On the other hand, the use of system-in-package techniques enables all devices to be embedded in a single package, and thus, realizations of product minimization and various functions while reducing power consumption. SIP techniques are being widely applied to memories, logic devices, sensors and converters, etc. In a systems-in-package structure, a plurality of semiconductor chips laminated using via conductors that pass though the semiconductor chips are electrically connected to each other, and the semiconductor chips are electrically connected to printed circuit boards (hereinafter, referred to as “PCBs”).

However, the use of a via conductor for such systems-in-packages disadvantageously involves a complicated fabrication process. For example, methods for fabricating systems-in-packages further requires, in addition to a process for forming via conductors on and/or over semiconductor chips, a process for forming conductors to connect the via conductors to pads and a process for forming bumps to electrically connect the semiconductor chips to other semiconductor chips arranged on the pads or PCBs. These various process steps disadvantageously complicates the overall fabrication process. Furthermore, when a metal material such as copper (Cu), which is difficult to etch, is used to form the bumps, chemical mechanical polishing (hereinafter, referred to as “CMP”) to pattern the copper layer is further required, thus further complicating the overall fabrication process.

### SUMMARY

Embodiments relate to a method for fabricating a semiconductor device package such as a system-in-package such that a plurality of semiconductor chips may be connected to each other in a laminated structure.

Embodiments relate to a system-in-package and a method for fabricating the same that may include a plurality of semiconductor chips laminated together, whereby a fabrication process can be simplified by forming a via conductor and a bump simultaneously.

Embodiments relate to a method for fabricating a system-in-package that can include at least one of the following steps: forming a passivation film on and/or over a semiconductor substrate provided with a metal line; and then patterning the passivation film to form first and second openings; and then forming a pad such that the pad covers the first and second openings and is connected to the metal line through the first opening; and then forming a photoresist on and/or over the passivation film provided with the pad; and then forming a deep trench in a region overlapping the second opening such that the deep trench passes through the photoresist and the pad, and extends to a predetermined depth in the semiconductor substrate; and then forming a via conductor inside the deep trench such that the via conductor comes in side-contact with the pad; and then removing the photoresist to protrude one end of the via conductor as a first bump; and then electrically connecting the first bump to another semiconductor chip or a printed circuit board.

Embodiments relate to a system-in-package having a structure in which a plurality of semiconductor chips are laminated, wherein at least one semiconductor chip includes at least one of the following: a passivation film formed on and/or over a semiconductor substrate provided with a metal line, the passivation film provided with first and second openings; a pad arranged on and/or over the passivation film, the pad adapted to cover the first and second openings and also configured for connection to the metal line through the first opening; a via conductor arranged in a region overlapping the second opening in which the via conductor passes through the pad and the semiconductor substrate, and is in side-contact with the pad; and a first bump integrated with the via conductor, the first bump protruding from the pad.

### DRAWINGS

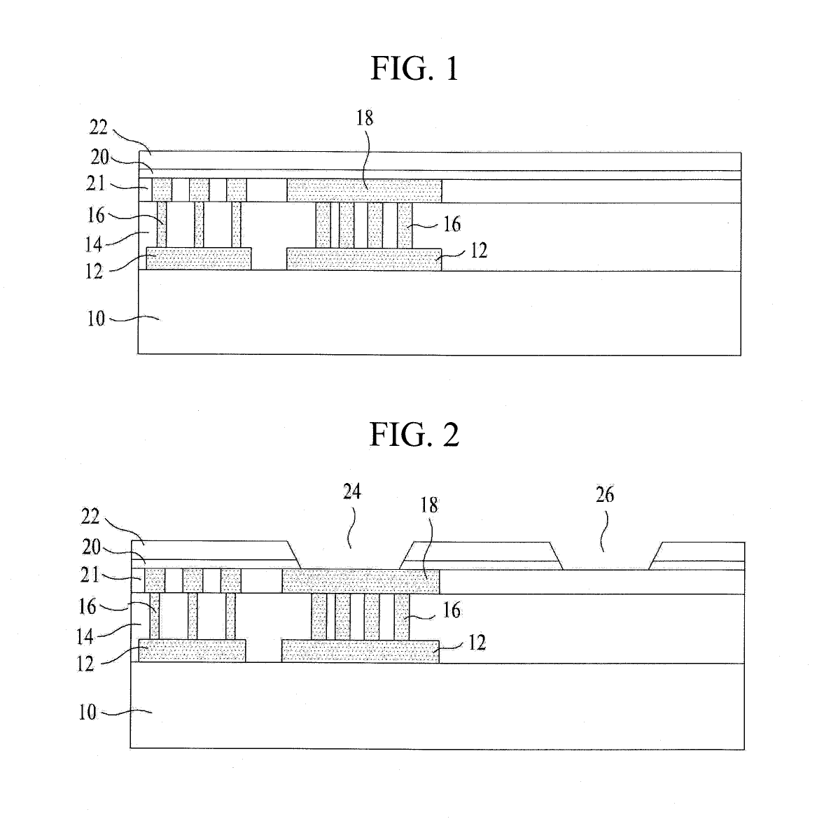

Example FIGS. 1 to 12 illustrate a method for fabricating a system in package in sequence, in accordance with embodiments.

### DESCRIPTION

Other aspects, features and advantages of the present invention will be more clearly understood from the following detailed description taken in conjunction with the accompanying drawings.

As illustrated in example FIGS. 1 to 12, a method for fabricating a system-in-package in accordance with embodiments may include forming pad 30 on and/or over first semiconductor chip 50, forming via conductor 42 such that via conductor 42 is integrated with first and second bumps 42A and 42B and passes through the structure from pad 30 to semiconductor substrate 10, and bonding first semiconductor chip 50 to second semiconductor chip 60 and PCB 70 in a laminated structure. In accordance with embodiments, although via conductor 42 may be formed using copper (Cu) as a metal having a low resistance, embodiments are not limited thereto.

As illustrated in example FIG. 1, a lower structure suitable for a semiconductor chip may be formed on and/or over semiconductor substrate 10. The lower structure includes a plurality of metal lines and insulating films. Example FIG. 1 schematically illustrates one example where the lower structure includes a plurality of lower metal lines 12 and upper metal lines 18 formed on and/or over semiconductor substrate 10. A plurality of contacts 16 are formed to electrically connect upper metal lines 18 to lower metal lines 12, respectively, while passing through first insulating film 14 formed between upper metal lines 18 and lower metal lines 12. Second insulating film 21 is formed in which upper metal lines 18 are embedded. In the case where copper (Cu) is used for upper metal line 18, insulating film 21 may be patterned to form a trench where upper metal line 18 is to be formed, the copper deposited such that the copper is embedded in the trench and covers the surface of insulating film 21, and the copper is then etched by CMP until the insulating film 21 is exposed, thereby forming upper metal line 18 having an uppermost surface that is coplanar with the uppermost surface of insulating film 21. First and second passivation films 20 and 22 having a double-layer structure may then be formed on and/or over upper metal line 18—embedded insulating film 21. First passivation film 20 may be formed to a thickness of about 2,000 to 3,000 Å by depositing a nitride insulator such as SiNₓ. Second passivation film 22 may be formed to a thickness of about 6,000 to 10,000 Å by depositing an oxide insulator having a low dielectric constant, e.g., TEOS (tetra ethyl ortho silicate).

As illustrated in example FIG. 2, first and second passivation films 20 and 22 may then be patterned by photolithographic and etching processes to form first and second openings 24 and 26. First opening 24 exposes upper metal line 18 that will be electrically connected to a pad to be formed in a subsequent process. Second opening 26 provides a region where a via conductor is to be formed in a subsequent process.

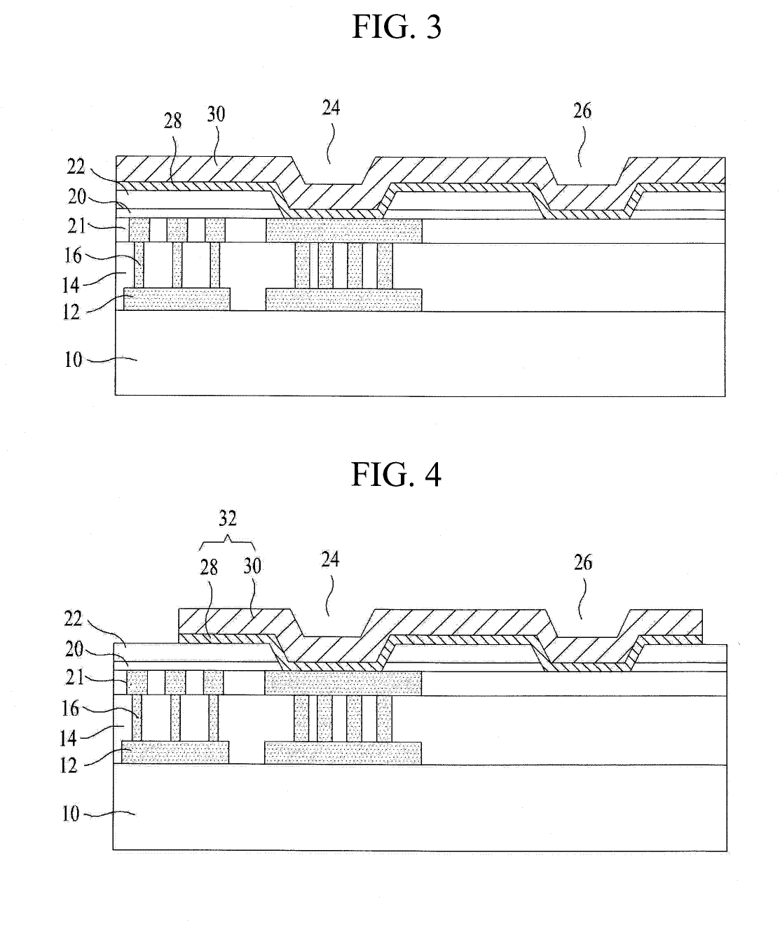

As illustrated in example FIG. 3, barrier metal 28 and pad metal 30 may then be sequentially formed on and/or over second passivation film 22 provided with openings 24 and 26. For example, in the case where an aluminum (Al) pad is formed, aluminum pad barrier metal 28 and aluminum metal 30 may be deposited on and/or over second passivation film 22.

As illustrated in example FIG. 4, pad metal 30 and barrier metal 28 may then be patterned by photolithographic and etching processes to form pad 32 covering first and second openings 24 and 26. Pad 32, where barrier metal 28 and the pad metal 30 are laminated, may be electrically connected to upper metal line 18 through first opening 24.

As illustrated in example FIG. 5, photoresist 34 may then be coated on and/or over second passivation film 22 provided with pad 32. For example, photoresist 34 may be coated to a thickness of about 2 to 10 μm and may be selected from those having a high selectivity of about 90:1.

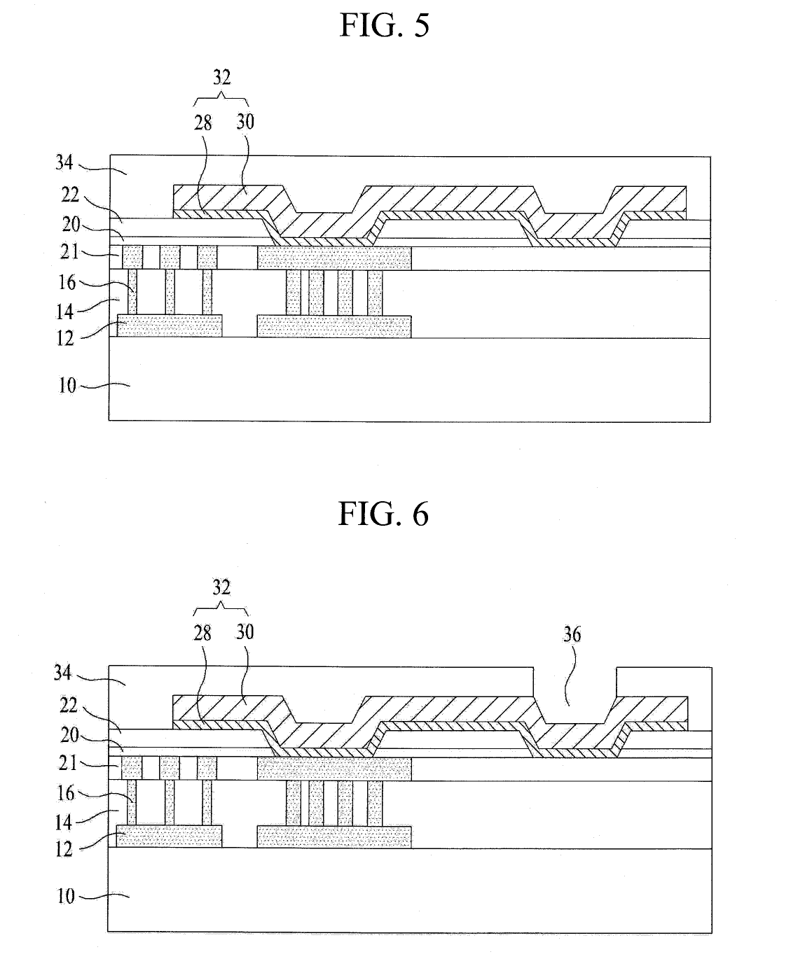

As illustrated in example FIG. 6, photoresist 34 may be patterned by a photolithographic process to form trench 36 to open a region where the subsequent via conductor is to be formed. Trench 36 passing through photoresist 34 overlaps second opening 26 of first and second passivation films 20 and 22 illustrated in example FIG. 2.

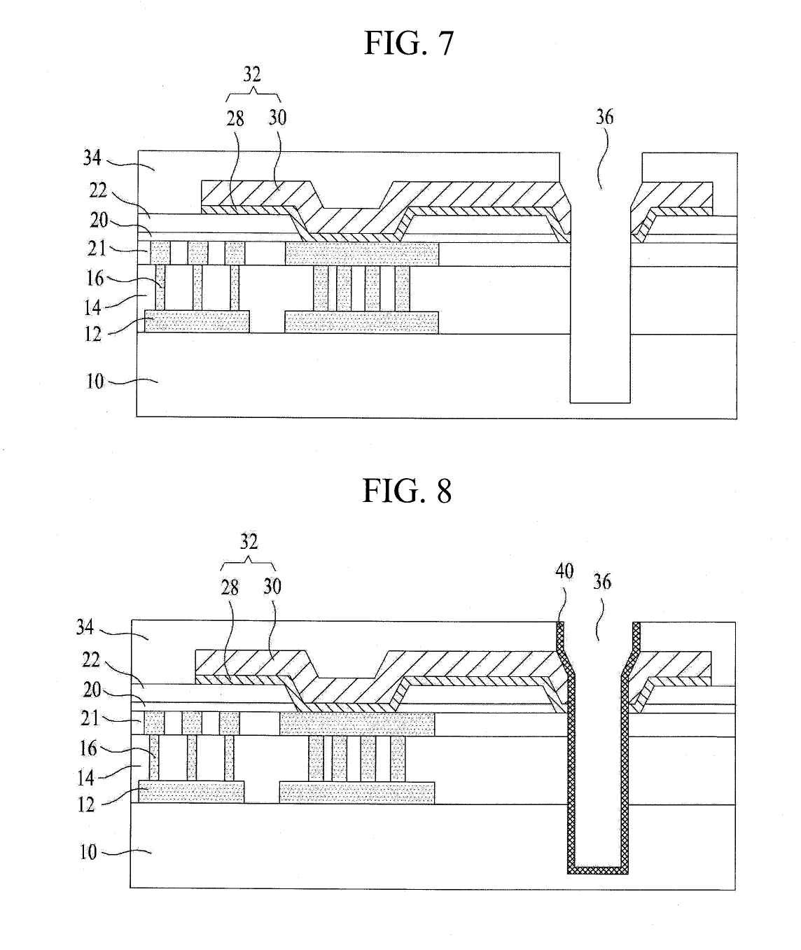

As illustrated in example FIG. 7, deep trench 36 passes through photoresist 34, pad 32, insulating films 14 and 21, passivation films 20 and 22 and extends to a predetermined depth in semiconductor substrate 10. Deep trench 36 may be formed using rapid-etching equipment such that deep trench 36 passes through pad 32 and insulating films 14 and 21, and extends to a predetermined depth in semiconductor substrate 10, while not passing completely through semiconductor substrate 10. For example, deep trench 36 may have a width of about 10 to 30 μm and a depth of about 40 to 100 μm. Deep trench 36 may pass through pad 32 such that the side surface (e.g., inclined and vertical side-surfaces) of pad 32 is exposed.

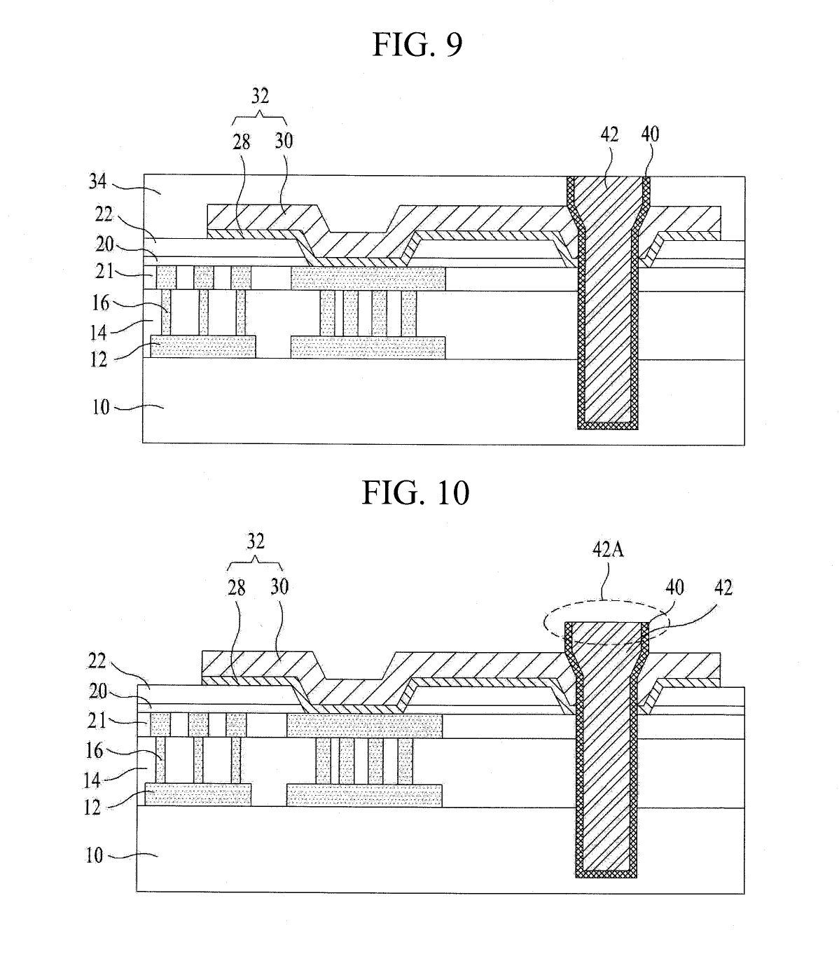

As illustrated in example FIGS. 8 and 9, barrier metal 40 may then be formed on and/or over sidewalls of deep trench 36. A metal material such as copper may then be embedded in deep trench 36 to form via conductor 42. A copper annealing process may then be performed. In the case where an organic insulator is used for semiconductor substrate 10 or insulating film 14, barrier metal 40 may be formed in order to prevent the copper from being diffused into organic insulating film 14. Barrier metal 40 may be a metal such as at least one of Ti, TiN, TiSiN, Ta and TaN. A seed metal may then be formed on barrier metal 40 and then subjected to copper plating using electroplating or electroless plating to form copper via conductor 42 completely filling deep trench 36. Copper via conductor 42 may then be subjected to annealing at 150 to 250° C. for 20 to 120 minutes for the purpose of stabilization. Via conductor 42 may be connected through barrier metal 40 to the side surface (e.g. inclined and vertical side-surfaces) of pad 32. In order words, via conductor 42 may be in side-contact with pad 32. Via conductor 42 may be formed such that it has a length of approximately 10 to 20 μm.

As illustrated in example FIG. 10, photoresist 34 is etched such that the upper portion of via conductor 42 protrudes from pad 32 to the outside. The protrusion of via conductor 42 upward from pad 32 serves as first bump 42A that may be electrically connected to another semiconductor chip or the PCB.

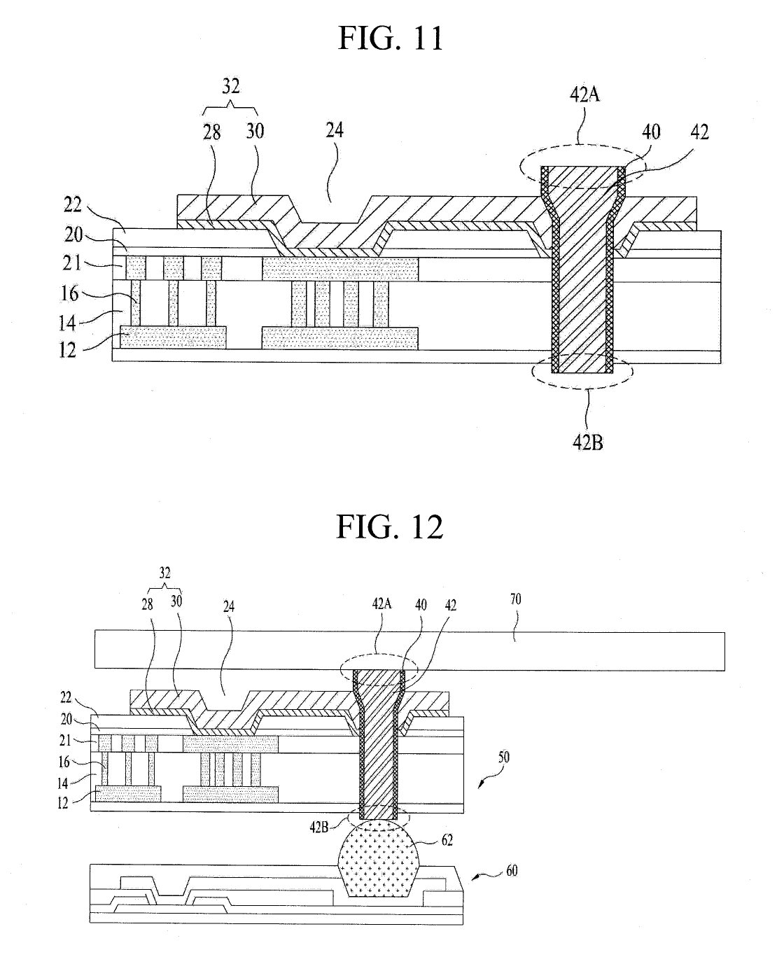

As illustrated in example FIG. 11, the rear surface of semiconductor substrate 10 may then be subjected to grinding and etching such that the lower portion of via conductor 42 protrudes from substrate 10 to the outside. The rear surface of semiconductor substrate 10 may be subjected to back grinding with an etching method using a higher silicon etch ratio until via conductor 42 is exposed. Since the etch ratio of via conductor 42 is lower than that of semiconductor substrate 10, the lower portion of via conductor 42 protrudes from the bottom. Via conductor 42 that protrudes downward from semiconductor substrate 10 may thereby serve as second bump 42B that may be electrically connected to another semiconductor chip or the PCB. The back grinding of semiconductor substrate 10 renders barrier metal 40 present in the lower portion of via conductor 42 to be etched, enabling the rear surface of via conductor 42 to be exposed. Accordingly, via conductor 42 passing through semiconductor chip 50 may be formed integrally with first and second bumps 42A and 42B having protrusion structure at the same time, via conductor 42 passes through pad 32 and comes in side-contact with pad 32. Accordingly, it is possible to eliminate the necessity of additional processes including a process for forming a conductor connecting the pad to the via conductor, a process for forming a bump, and a copper CMP process, and thus to reduce the total number of processes.

In the case where since semiconductor chip 50 is present as the outermost layer, it may be unnecessary to electrically connect the rear surface of semiconductor substrate 10 to other devices, in order words, there is no need for second bump 42B, the process for back-grinding semiconductor substrate 10 as illustrated in example FIG. 11 may be omitted.

As illustrated in example FIG. 12, a bonding process may be performed to join semiconductor chip 50 illustrated in example FIG. 11 to another semiconductor chip 60 and PCB 70 in the form of a laminate. For example, a bonding process may be performed such that second bump 42B integrated with via conductor 42 of semiconductor chip 50, while protruding from the semiconductor substrate 10, is electrically connected to bump 60 of another semiconductor chip 60. Furthermore, a bonding process may be performed such that first bump 42A integrated with via conductor 42 of semiconductor chip 50, while protruding from pad 32, is electrically connected to PCB 70.

As apparent from the afore-going, according to the semiconductor device package and a fabrication method thereof, the via conductor that is in side-contact with the pad and is thus directly connected thereto is formed integrally with the bumps at the same time. As a result, it is possible to reduce the total number of processes and fabrication costs and thus to improve fabrication efficiency.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a passivation film over a semiconductor substrate provided with a metal line; and then
patterning the passivation film to form first and second openings; and then
forming a pad over the first and second openings and connected to the metal line through the first opening; and then
forming a photoresist over the passivation film including the pad; and then
forming a deep trench in a region corresponding spatially to the second opening and extending through the photoresist and the pad and passivation film and into the semiconductor substrate to a predetermined depth; and then
forming a via conductor in the deep trench such that the via conductor directly contacts the pad; and then
forming a first bump by removing the photoresist such that one end of the via conductor protrudes to the outside; and then
electrically connecting the first bump to at least one of a second semiconductor chip and a printed circuit board.

2. The method of claim 1, wherein forming the passivation film comprises:
forming a nitride film as a first passivation film over the semiconductor substrate; and then
forming an oxide film as a second passivation film over the nitride film.

3. The method of claim 2, wherein the nitride film comprises a silicon nitride (SiNₓ) film and the oxide film comprises a tetra ethyl ortho silicate (TEOS) film.

4. The method of claim 3, wherein the silicon nitride film is formed to a thickness ranging from 2,000 to 3,000 Å and the TEOS film is formed to a thickness ranging from 6,000 to 10,000 Å.

5. The method of claim 1, wherein the photoresist is formed to a thickness ranging from 2 to 10 μm.

6. The method of claim 5, wherein the photoresist has an etch selectivity of 90:1.

7. The method of claim 1, wherein the deep trench is formed having a width ranging from 10 to 30 μm and a depth about 40-100 μm.

8. The method of claim 1, further comprising, after forming the deep trench but before forming the via conductor:
sequentially forming a barrier metal on sidewalls of the deep trench and a seed metal in the deep trench; and then
subjecting the seed metal to a plating process to thereby form via conductor; and then
subjecting the via conductor to an annealing process.

9. The method of claim 8, wherein the via conductor comprises a copper material.

10. The method of claim 9, wherein the via conductor is formed using at least one of electroplating and electroless plating.

11. The method of claim 8, wherein the barrier metal comprises at least one of Ti, TiN, TiSiN, Ta and TaN.

12. The method of claim 8, wherein the via conductor is formed to a thickness ranging from 10 to 20 μm.

13. The method of claim 8, wherein the annealing process is performed at 150 to 250° C. for 20 to 120 minutes.

14. The method of claim 1, further comprising, after forming the first bump:
forming a second bump by etching the rear surface of the semiconductor substrate to protrude the other end of the via conductor.

15. An apparatus comprising:
a semiconductor substrate;
a metal line formed on the semiconductor substrate;
a passivation film formed over the semiconductor substrate including the metal line, wherein the passivation film includes first and second openings;
a pad formed over the passivation film and covering the first and second openings for connection to the metal line through the first opening;
a via conductor extending through the pad, the passivation film and the semiconductor substrate such that the via conductor is in direct contact with the pad,
wherein the via conductor includes a first exposed end protruding from the pad and which serves as a first bump.

16. The apparatus of claim 15, wherein the via conductor includes a second exposed end protruding from the semiconductor substrate and which serves as a second bump.

17. The apparatus of claim 15, wherein the passivation film comprises a multi-layered structure.

18. The apparatus of claim 17, wherein the multi-layered structure comprises:
a nitride film formed as a first passivation film over the semiconductor substrate; and
an oxide film formed as a second passivation film over the nitride film.

19. The apparatus of claim 18, wherein the nitride film comprises a silicon nitride (SiNₓ) film formed to a thickness ranging from 2,000 to 3,000 Å.

20. The apparatus of claim 18, wherein the oxide film comprises a tetra ethyl ortho silicate (TEOS) film formed to a thickness ranging from 6,000 to 10,000 Å.
